(19) United States
(12) Patent Application Publication
(10) Pub. No.: US 2022/0005701 A1
(43) Pub. Date: Jan. 6, 2022

(54) ETCHING PROTECTION LAYER STRUCTURE OF METAL SEMICONDUCTOR JUNCTION AND MANUFACTURING METHOD THEREOF

(71) Applicant: LuxNet Corporation, Taoyuan City (TW)

(72) Inventor: YU-LUN WU, Taoyuan City (TW)

(21) Appl. No.: 17/197,084

(22) Filed: Mar. 10, 2021

(30) Foreign Application Priority Data
Jul. 2, 2020 (TW) 109122350

(51) Int. Cl. H01L 21/308; H01L 21/033; H01J 37/305

(52) U.S. Cl. CPC H01L 21/3081; H01J 37/3053; H01L 21/0332

(57) ABSTRACT

An etching protection layer structure of a metal semiconductor junction includes a semiconductor substrate and a metal etching protection layer. The semiconductor substrate has a metal semiconductor contact layer. The metal etching protection layer is disposed on the metal semiconductor contact layer, and serves as an etching mask for the ridge structure of laser device during the inductively coupled plasma reactive ion etching (ICP-RIE) process. The disclosure is not necessary to remove the metal etching protection layer after completing the etching process.

### CROSS REFERENCE TO RELATED APPLICATION

This application claims the benefits of Taiwan application Serial No. 109122350, filed on Jul. 2, 2020, the disclosures of which are incorporated by references herein in its entirety.

### TECHNICAL FIELD

The present invention relates to an etching protection layer of metal semiconductor junction, in particular to an etching protection layer structure of metal semiconductor junction and manufacturing method thereof.

### BACKGROUND

A highly doped contact layer of the metal semiconductor junction is susceptible to physical and chemical damage due to the cleaning or etching process of high-power plasma during the production process of each process station. This increases the density of surface defects or severely damages the surface of the contact layer, thereby changing the photoelectric characteristics of the device, and even electrical effects that cannot be remedied by the high temperature annealing process.

Materials such as titanium nitride (TiN), silicon nitride (SiN), and silicon dioxide (SiO₂) commonly used as hard masks for the ridge structure of a laser device in the inductively coupled plasma reactive ion etching (ICP-RIE) process must be removed at the end of the process.

### SUMMARY

The present invention uses titanium (Ti)/platinum (Pt) as the etching protection layer (ridge metal) of the semiconductor contact layer above the ridge waveguide of the laser device to avoid damage to the surface caused by the high-power plasma during the manufacturing process, so as to ensure that the photoelectric characteristics of the device are not affected and reduce the reliability risk.

An objective of the present invention is to provide an etching protection layer structure of metal semiconductor junction and manufacturing method thereof. The metal etching protection layer can serve as an etching mask for a ridge structure of laser device during an inductively coupled plasma reactive ion etching (ICP-RIE) process.

The present invention achieves the above-indicated objective by providing an etching protection layer structure of metal semiconductor junction including a semiconductor substrate and a metal etching protection layer. The semiconductor substrate has a metal semiconductor contact layer. The metal etching protection layer is disposed on the metal semiconductor contact layer, and serves as an etching mask for the ridge structure of laser device during the inductively coupled plasma reactive ion etching (ICP-RIE) process. The metal etching protection layer is not necessary to remove after completing the ICP-RIE process.

Compared to a conventional hard mask, the present invention has several advantages:

1. The metal etching protection layer of the present invention can serve as an etching mask for a ridge structure of laser device during an inductively coupled plasma reactive ion etching (ICP-RIE) process, and the metal etching protection layer is not necessary to remove after completing the ICP-RIE process.
2. The metal etching protection layer (ridge metal) not only protects the semiconductor contact layer from high-power plasma resulting in surface damage and defects, and it can replace the materials commonly used as hard masks for etching, such as dielectric materials TiN, SiN, SiO₂. The metal etching protection layer (ridge metal) can meet the same protecting function as the dielectric material etching mask, and can be used in the ICP-RIE dry etching process to make laser ridge waveguides to achieve the dual-use effect of the protection layer and the etching mask. After the dry etching process is completed, there is no need to remove the ridge metal, but the aforementioned dielectric material etching mask must be removed at the end of the process.

### BRIEF DESCRIPTION OF THE DRAWINGS

FIG. 1 is a schematic diagram of an etching protection layer structure of metal semiconductor junction of the present invention.

FIGS. 2 to 5 are schematic diagrams of a method for manufacturing an etching protection layer structure of a metal semiconductor junction of the present invention.

FIG. 6 is a flowchart of a method for manufacturing an etching protection layer structure of a metal semiconductor junction of the present invention.

### DETAILED DESCRIPTION

The etching protection layer of the present invention serves as an etching mask for a ridge structure of laser device during an inductively coupled plasma reactive ion etching (ICP-RIE) process, and the metal etching protection layer is not necessary to remove after completing the ICP-RIE process.

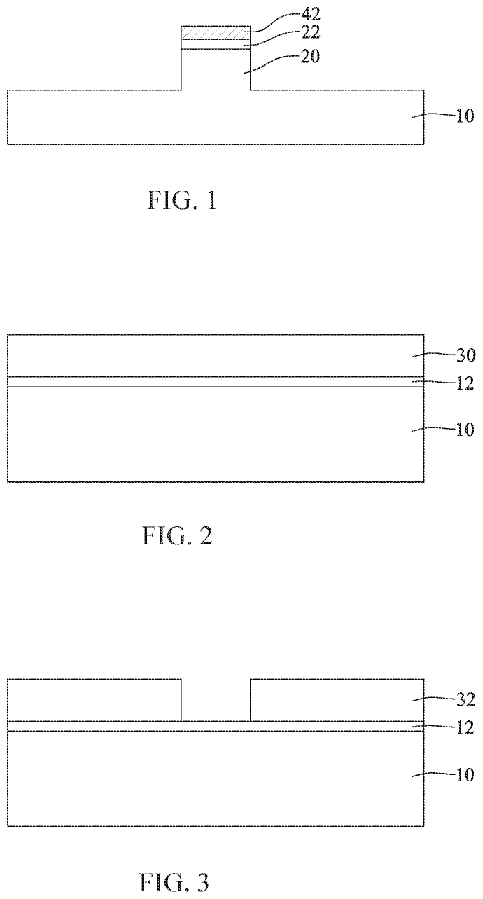

FIG. 1 is a schematic diagram of an etching protection layer structure of metal semiconductor junction of the present invention. As shown in FIG. 1, a semiconductor substrate 10 has a metal semiconductor contact layer 22. The semiconductor substrate 10 can be silicon, germanium or III-V semiconductor, including gallium arsenide GaAs or gallium nitride GaN or indium phosphide InP.

A metal etching protection layer 42 is disposed on the metal semiconductor contact layer 22, and serves as an etching mask for a ridge structure 20 of laser device during an inductively coupled plasma reactive ion etching (ICP-RIE) process. The metal etching protection layer 42 is not necessary to remove after completing the ICP-RIE process. The metal etching protection layer 42 is a P-type metal of platinum (Pt), titanium (Ti)/platinum (Pt), or titanium (Ti)/platinum (Pt)/gold (Au). The present invention uses titanium (Ti)/platinum (Pt) as an etching protection layer (ridge metal) of the metal semiconductor contact layer 22 above the ridge structure 20 (waveguide).

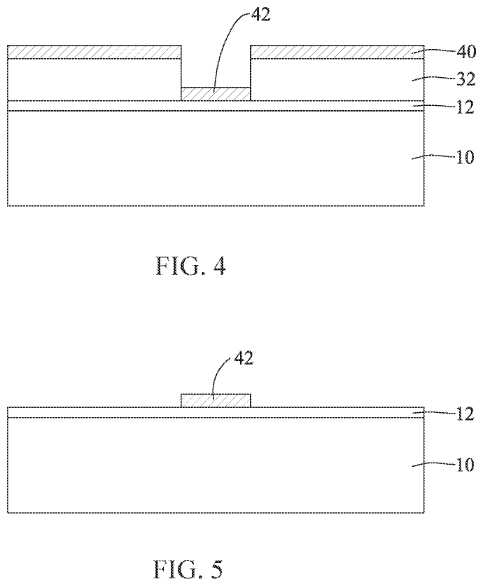

FIGS. 2 to 5 are schematic diagrams of a method for manufacturing an etching protection layer structure of a metal semiconductor junction of the present invention. As shown in FIG. 2, a semiconductor substrate 10 with a metal semiconductor contact layer 12 is provided.

Next, a photolithography process is used to define a pattern of metal etching protection layer 32 on the semiconductor substrate 10. A pretreatment process of this photolithography process is to first remove the surface oxide layer of the semiconductor substrate 10. And, a photoresist 30 is coated on the semiconductor substrate 10. A photomask is used to expose on the photoresist 30 to define the pattern of metal etching protection layer 32. Then, the photoresist 30 is developed to form the pattern of the protection layer pattern 32, as shown in FIG. 3.

Next, as shown in FIG. 4, a metal protection layer 40 is deposited on the pattern of metal etching protection layer 32. The surface contaminants and oxides of the semiconductor substrate 10 are removed by dry etching and wet etching processes before depositing the metal protection layer. An electron beam evaporation machine is used to deposit the metal protection layer 40. The metal protection layer 40 is a P-type metal of platinum (Pt), titanium (Ti)/platinum (Pt), or titanium (Ti)/platinum (Pt)/gold (Au). Generally, the selection of P-type electrode metal must consider the work function of the junction with the semiconductor. Generally, the metal of the P-type electrode can be a gold-zinc (Au—Zn)/gold (Au), or a titanium (Ti)/platinum (Pt)/gold (Au) metal alloy. Au—Zn/Au is an alloy ohmic contact and each layer is deposited on the cladding layer or the metal contact layer by evaporation. The alloy needs to be heated to a temperature of 350-400° C. for 30 minutes to form a good ohmic contact.

Next, as shown in FIG. 5, the metal protection layer 40 other than the pattern of metal etching protection layer 32 is removed to form a metal etching protection layer 42. After depositing the metal protection layer 40 using the electron beam evaporation machine, a metal lift-off process is used to remove the metal outside the defined region, and the metal etching protection layer 42 is completed. A metal etching protection layer 42 serves as an etching mask for a ridge structure 20 of laser device during an inductively coupled plasma reactive ion etching (ICP-RIE) process. The metal etching protection layer 42 is not necessary to remove after completing the ICP-RIE process, as shown in FIG. 1.

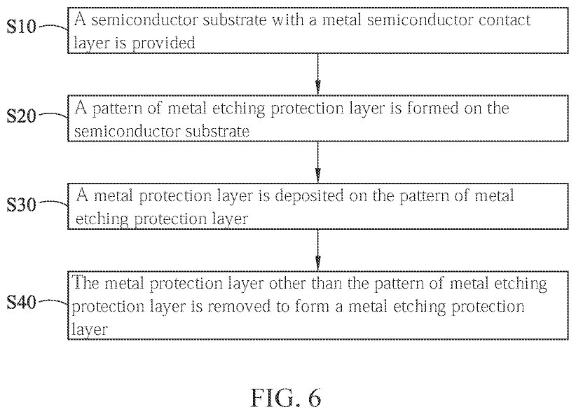

FIG. 6 is a flowchart of a method for manufacturing an etching protection layer structure of a metal semiconductor junction of the present invention. First, as shown in FIG. 6, a semiconductor substrate with a metal semiconductor contact layer is provided, as shown in step S10. Next, a pattern of metal etching protection layer is formed on the semiconductor substrate, as shown in step S20. Next, a metal protection layer is deposited on the pattern of metal etching protection layer, as shown in step S30. Finally, the metal protection layer other than the pattern of metal etching protection layer is removed to form a metal etching protection layer, as shown in step S40.

What is claimed is:

1. An etching protection layer structure of a metal semiconductor junction, comprising:
a semiconductor substrate, having a metal semiconductor contact layer; and
a metal etching protection layer, disposed on the metal semiconductor contact layer, the metal etching protection layer serving as an etching mask for a ridge structure of laser device during an inductively coupled plasma reactive ion etching (ICP-RIE) process, wherein the metal etching protection layer is not necessary to remove after completing the ICP-RIE process.

2. The etching protection layer structure of a metal semiconductor junction as recited in claim 1, wherein the metal etching protection layer is formed with processes of forming a pattern of metal etching protection layer on the semiconductor substrate, then depositing a metal protection layer on the pattern of metal etching protection layer, and removing the metal protection layer other than the pattern of metal etching protection layer.

3. The etching protection layer structure of a metal semiconductor junction as recited in claim 1, wherein the metal etching protection layer is a P-type metal of platinum (Pt), titanium (Ti)/platinum (Pt), or titanium (Ti)/platinum (Pt)/gold (Au).

4. A method for manufacturing an etching protection layer structure of a metal semiconductor junction, comprising the steps of:
providing a semiconductor substrate having a metal semiconductor contact layer;
forming a pattern of metal etching protection layer on the semiconductor substrate;
depositing a metal protection layer on the pattern of metal etching protection layer; and
removing the metal protection layer other than the pattern of metal etching protection layer to form a metal etching protection layer.

5. The method for manufacturing an etching protection layer structure of a metal semiconductor junction as recited in claim 4, wherein forming the pattern of metal etching protection layer, further comprising steps of:
removing a surface oxide layer of the semiconductor substrate;
coating a photoresist on the semiconductor substrate;
using a photomask to expose on the photoresist to define the pattern of metal etching protection layer; and
developing the photoresist to form the pattern of metal etching protection layer.

6. The method for manufacturing an etching protection layer structure of a metal semiconductor junction as recited in claim 4, wherein depositing the metal protection layer, further comprising steps of:
using dry etching and wet etching processes to remove surface contaminants and oxides of the semiconductor substrate before depositing the metal protection layer; and
using an electron beam evaporation machine to deposit the metal protection layer, wherein the metal protection layer is a P-type metal of platinum (Pt), titanium (Ti)/platinum (Pt), or titanium (Ti)/platinum (Pt)/gold (Au).

7. The method for manufacturing an etching protection layer structure of a metal semiconductor junction as recited in claim 4, wherein the metal etching protection layer serves as an etching mask for a ridge structure of laser device during an inductively coupled plasma reactive ion etching (ICP-RIE) process, and the metal etching protection layer is not necessary to remove after completing the ICP-RIE process.
